(19) United States
(12) Patent Application Publication
(10) Pub. No.: US 2026/0327473 A1
(43) Pub. Date: Oct. 22, 2026

(54) THERMALLY CONDUCTIVE SHEET

(71) Applicant: KANEKA CORPORATION, Osaka (JP)

(72) Inventor: Yasushi NISHIKAWA, Osaka (JP)

(73) Assignee: KANEKA CORPORATION, Osaka (JP)

(21) Appl. No.: 19/290,940

(22) Filed: Aug. 5, 2025

(30) Foreign Application Priority Data
Aug. 9, 2024 (JP) 2024-134535

(51) Int. Cl. C09K 5/14; C08K 3/04; C08L 33/02; H05K 7/20

(52) U.S. Cl. CPC C09K 5/14; C08K 3/042; C08L 33/02; H05K 7/2039

(57) ABSTRACT

As a thermally conductive sheet that has an excellent temporary pasting property and excellent adhesion in addition to excellent thermal conductivity, provided is a thermally conductive sheet that contains a composition containing graphite particles (A) and an organic polymer compound (B), the graphite particles (A) being oriented in a thickness direction of the thermally conductive sheet, the thermally conductive sheet having: a tensile strength of less than 0.8 MPa in at least one of an X direction and a Y direction; and a ratio of the tensile strength in the X direction to the tensile strength in the Y direction of more than 2.2 times.

This Nonprovisional application claims priority under 35 U.S.C. § 119 on Patent Application No. 2024-134535 filed in Japan on Aug. 9, 2024, the entire contents of which are hereby incorporated by reference.

### TECHNICAL FIELD

The present invention relates to a thermally conductive sheet.

### BACKGROUND ART

A technique for preventing or reducing temperature increases by attaching a heat-dissipating body to a heat-generating body such as an electronic component is conventionally known. In a case where this heat-dissipating body is used, a member that is in sheet form and that has thermal conductivity (thermally conductive sheet) is used to efficiently transmit heat from the heat-generating body to the heat-dissipating body. Further, the thermally conductive sheet is required to have adhesion to an adherend.

A thermally conductive sheet containing a composition containing graphite particles, which are oriented in a thickness direction of the thermally conductive sheet, and an organic polymer compound is known as a thermally conductive sheet that has thermal conductivity and adhesion to an adherend (see, for example, Patent Literatures 1 to 5).

### CITATION LIST

### Patent Literature

### Patent Literature 1

Japanese Patent Application Publication Tokukai No. 2023-016528

### Patent Literature 2

Japanese Patent Application Publication Tokukai No. 2023-151582

### Patent Literature 3

Pamphlet of International Publication No. WO 2023/15761

### Patent Literature 4

Japanese Patent Application Publication Tokukai No. 2020-55893

### Patent Literature 5

Japanese Patent Application Publication Tokukai No. 2022-129990

### Patent Literature 6

Japanese Patent Application Publication Tokukai No. 2023-49931

### SUMMARY OF INVENTION

### Technical Problem

Thermally conductive sheets disclosed in Patent Literatures 1 to 6 have a certain thermal conductivity and a certain adhesion. Meanwhile, in recent years, in servers, super computers, and electric control units (ECUs) of automobiles, a high-performance CPU, a high-performance GPU, and the like are employed. Thus, a temperature of a chip tends to increase in accordance with, for example, an increase in information processing amount and an improvement in processing speed. Such a temperature increase of the chip causes a deterioration in performance of a CPU or the like. For this reason, more efficient heat dissipation even under a high-temperature environment is required. In order to deal with such an application, there is a demand for a thermally conductive sheet that has a lower thermal resistance and a higher thermal conductivity than a conventional thermally conductive sheet. Moreover, typically, a thermally conductive sheet is stored in a state in which the thermally conductive sheet adheres to a backing sheet. When temporarily attached to an adherend, the thermally conductive sheet is peeled off from the backing sheet and then temporarily attached to the adherend. Here, a conventional thermally conductive sheet such as the thermally conductive sheets disclosed in Patent Literatures 1 to 5 had room for improvement in terms of ease of peeling from the backing sheet and ease of attachment to an adherend, that is, a temporary attachment property. Further, the conventional thermally conductive sheet had room for improvement in terms of adhesion to an adherend, for example, adhesion to a heat-generating body and a heat sink in a case where the conventional thermally conductive sheet is bonded, by heating, to the heat-generating body and the heat sink which serve as adherends.

In light of the above, an object of an aspect of the present invention is to provide a thermally conductive sheet that has an excellent temporary attachment property and excellent adhesion in addition to excellent thermal conductivity.

### Solution to Problem

In order to attain the object, a thermally conductive sheet in accordance with an embodiment of the present invention is a thermally conductive sheet containing a composition containing graphite particles (A) and (B),
the graphite particles (A) being oriented in a thickness direction of the thermally conductive sheet,
the thermally conductive sheet having:
a tensile strength of less than 0.8 MPa in at least one of an X direction and a Y direction; and
a ratio of the tensile strength in the X direction to the tensile strength in the Y direction (the tensile strength in the X direction/the tensile strength in the Y direction) of more than 2.2 times.

### Advantageous Effects of Invention

An aspect of the present invention makes it possible to provide a thermally conductive sheet that has an excellent temporary attachment property and excellent adhesion in addition to excellent thermal conductivity. Thus, the thermally conductive sheet can be favorably employed in applications that require efficient heat dissipation.

### DESCRIPTION OF EMBODIMENTS

The following description will discuss embodiments of the present invention, but the present invention is not limited to the embodiments. The present invention is not limited to the configurations described below, but may be altered in various ways within the scope of the claims. The present invention also encompasses, in its technical scope, any embodiment or example derived by combining technical means disclosed in differing embodiments or examples. Further, it is possible to form a new technical feature by combining the technical means disclosed in the respective embodiments. Note that all academic documents and patent literatures cited herein are incorporated herein by reference. Any numerical range expressed as “A to B” herein means “not less than A but not more than B (i.e., a range from A to B which includes both A and B)” unless otherwise stated.

### [1. Thermally Conductive Sheet]

A thermally conductive sheet in accordance with an embodiment of the present invention is a thermally conductive sheet containing a composition containing graphite particles (A) and an organic polymer compound (B), the graphite particles (A) being oriented in a thickness direction of the thermally conductive sheet, the thermally conductive sheet having: a tensile strength of less than 0.8 MPa in at least one of an X direction and a Y direction; and a ratio of the tensile strength in the X direction to the tensile strength in the Y direction (the tensile strength in the X direction/the tensile strength in the Y direction) of more than 2.2 times.

### [1-1. Tensile Strength]

In the thermally conductive sheet in accordance with an embodiment of the present invention, the tensile strength in at least one of the X direction and the Y direction is less than 0.8 MPa, and the ratio of the tensile strength in the X direction to the tensile strength in the Y direction (the tensile strength in the X direction/the tensile strength in the Y direction) is more than 2.2 times.

In the present specification, “X direction” refers to an in-main-surface direction in which the thermal conductivity is highest in a case where the thermal conductivity is measured for a main surface of the thermally conductive sheet, and “Y direction” refers to an in-main-surface direction perpendicular to the X direction. Further, in the present specification, “main surface” refers to at least one main surface of the thermally conductive sheet.

Further, a thermally conductive sheet that is produced by a production method including the step of slicing a multilayer cross section of a laminate in which primary sheets (which will be described later) are layered may have a striped pattern corresponding to a multilayer structure made of the primary sheets. In a case where the thermally conductive sheet in accordance with an embodiment of the present invention has the striped pattern, typically, the X direction is perpendicular to a layer-stacking direction in the laminate. Specifically, the X direction may be parallel to lines of the striped pattern and correspond to horizontal surfaces of the primary sheets. Meanwhile, in the case where the thermally conductive sheet in accordance with an embodiment of the present invention has the striped pattern, typically, the Y direction corresponds to the layer-stacking direction in the laminate. Specifically, the Y direction may be perpendicular to the striped pattern and correspond to a thickness direction of the primary sheets, that is, a direction in which the primary sheets are stacked.

In the present specification, “tensile strength in the X direction” is also referred to as “tensile strength (X)”, “tensile strength in the Y direction” is also referred to as “tensile strength (Y)”, and “ratio of the tensile strength in the X direction to the tensile strength in the Y direction (the tensile strength in the X direction/the tensile strength in the Y direction)” is also referred to as “tensile strength ratio”. Further, in the present specification, the feature that “at least one of the tensile strength (X) and the tensile strength (Y) is less than 0.8 MPa, and the tensile strength ratio is more than 2.2 times” of the thermally conductive sheet in accordance with an embodiment of the present invention is also referred to as “feature A”.

In a case where the thermally conductive sheet is temporarily attached and in a case where the thermally conductive sheet is bonded to an adherend by heating, stress is applied to the thermally conductive sheet. Further, in a case where an environment test is carried out in which the thermally conductive sheet that is bonded to an adherend is maintained in a high-temperature state or exposed successively to a high temperature and a low temperature, materials constituting the thermally conductive sheet and the adherend expand and shrink due to changes in temperature and humidity. In other words, in the environment test, dimensions of the materials change. Such change in the dimensions also applies stress to the thermally conductive sheet.

Having the feature A in the thermally conductive sheet means in short that the tensile strength in the X direction or the Y direction is low. Here, the thermally conductive sheet having a low tensile strength in one direction can release, on a lower tensile strength side, the stress applied as described above. This leads to improvement in the temporary attachment property and the adhesion to an adherend. As a result, the thermally conductive sheet in accordance with an embodiment of the present invention has an excellent temporary attachment property and excellent adhesion.

In addition, in a thermally conductive sheet in accordance with an embodiment of the present invention, the graphite particles (A) are oriented in the thickness direction, so that the thermally conductive sheet exhibits excellent thermal conductivity (lower thermal resistance). In a case where the thermally conductive sheet has the feature A, the tensile strength ratio is more than 2.2 times and the tensile strength in one direction is high. Accordingly, a significant deformation can be prevented or a deformation can be reduced when the thermally conductive sheet is bonded. As a result, orientation of the graphite particles in the thickness direction can be maintained. Consequently, the thermally conductive sheet in accordance with an embodiment of the present invention has excellent thermal conductivity (low thermal resistance).

In light of the above, the thermally conductive sheet in accordance with an embodiment of the present invention yields an effect of having an excellent temporary attachment property and excellent adhesion in addition to excellent thermal conductivity.

Note that in the present specification, the adhesion includes adhesion in a case where the thermally conductive sheet is bonded to an adherend, that is, not only initial adhesion but also adhesion after maintaining the thermally conductive sheet at high temperature and adhesion after heat cycles. Here, the adhesion after maintaining the thermally conductive sheet at high temperature means adhesion between the thermally conductive sheet and an adherend in a case where, in a state in which the thermally conductive sheet is bonded to the adherend and caused to adhere to the adherend, the thermally conductive sheet is maintained in a high-temperature environment. Further, the adhesion after heat cycles means adhesion between the thermally conductive sheet and an adherend in a case where, in a state in which the thermally conductive sheet is bonded to the adherend and caused to adhere to the adherend, the thermally conductive sheet is maintained in an environment in which a high temperature and a low temperature are repeated.

A large tensile strength ratio means that a difference in tensile strength between the X direction and the Y direction is large. In that case, the stress described above is more easily transferred in a direction toward lower tensile strength, and more easily released. Thus, a higher tensile strength ratio improves more the temporary attachment property and the adhesion of the thermally conductive sheet in accordance with an embodiment of the present invention. From this viewpoint, in an embodiment of the present invention, the tensile strength ratio has a lower limit of more than 2.2 times, preferably not less than 3.0 times, and more preferably not less than 3.4 times.

Meanwhile, in a case where the tensile strength ratio is not more than a predetermined value, it is possible to suitably prevent accuracy of temporary attachment from decreasing due to an increase in dimensional change in the X direction and the Y direction at the time when the thermally conductive sheet is temporarily attached. Further, in a case where the tensile strength ratio is not more than a predetermined value, it is possible to suitably prevent a thermally conductive sheet from breaking on a lower tensile strength side due to force for bonding at the time when the thermally conductive sheet is bonded by heating. As a result, the adhesion can be further improved. Moreover, it is also possible to suitably prevent a thermally conductive sheet from being broken on a lower tensile strength side due to a dimensional change of the materials which is caused by temperature and humidity changes in the environment test. As a result, the adhesion can be further improved.

As described above, in the thermally conductive sheet in accordance with an embodiment of the present invention, the temporary attachment property and the adhesion can be improved in a case where the tensile strength ratio is not more than a predetermined value. From this viewpoint, in an embodiment of the present invention, the tensile strength ratio has a upper limit of preferably not more than 10.0 times, more preferably not more than 7.0 times, and even more preferably not more than 6.0 times.

In the thermally conductive sheet in accordance with an embodiment of the present invention, since the tensile strength ratio is more than 2.2 times, the tensile strength (Y) is smaller than the tensile strength (X). At least one of the tensile strength (Y) and the tensile strength (Y) is less than 0.80 MPa. Thus, in an embodiment of the present invention, the tensile strength (Y) is less than 0.80 MPa.

In an embodiment of the present invention, in a case where the tensile strength (Y) is low, the tensile strength ratio is large. Accordingly, the stress described above can be easily released in the Y direction in which the tensile strength is low. Thus, the temporary attachment property and the adhesion of the thermally conductive sheet in accordance with an embodiment of the present invention is considered to be further improved. From this viewpoint, in an embodiment of the present invention, the tensile strength (Y) is preferably less than 0.50 MPa, more preferably less than 0.30 MPa, and even more preferably not more than 0.25 MPa. Meanwhile, in view of strength of the thermally conductive sheet itself, the tensile strength (Y) is preferably not less than a predetermined value. Specifically, the tensile strength (Y) is preferably not less than 0.05 MPa, more preferably not less than 0.10 MPa, and even more preferably not less than 0.12 MPa.

In an embodiment of the present invention, in a case where the tensile strength (X) is low, it is possible to suitably control the tensile strength ratio in a range of not more than a predetermined value. Accordingly, for the reason described earlier, it is possible to further improve the temporary attachment property and the adhesion. From this viewpoint, in an embodiment of the present invention, the tensile strength (X) is preferably less than 2.00 MPa, more preferably less than 1.00 MPa, and even more preferably less than 0.70 MPa. Meanwhile, the tensile strength (X) is preferably not less than a predetermined value, from (i) the viewpoint of the strength of the thermally conductive sheet itself and (ii) the viewpoint of improving the thermal conductivity by adjusting the tensile strength ratio in a preferable range of not less than a predetermined value and maintaining the temporary attachment property, the adhesion, and the orientation of the graphite particles in the thickness direction. Specifically, the tensile strength (X) is preferably not less than 0.10 MPa, more preferably not less than 0.30 MPa, and even more preferably not less than 0.50 MPa.

In an embodiment of the present invention, a method for measuring the tensile strength (X) and the tensile strength (Y) is not particularly limited. A known method can be used as the method for measuring the tensile strength. The method can be, for example, the method described in Examples.

### [1-2. Composition Containing Graphite Particles (A) and Organic Polymer Compound (B)]

### (Graphite Particles (A))

In an embodiment of the present invention, the thermally conductive sheet containing the graphite particles (A) allows the graphite particles (A) that have thermal conductivity to be dispersed in the thermally conductive sheet. Thus, the thermally conductive sheet can have higher thermal conductivity. This makes it possible to reduce thermal resistance of the thermally conductive sheet.

The graphite particles (A) may have a shape that is either spherical or non-spherical. From the viewpoint that the graphite particles (A) being easily oriented makes it possible to improve thermal conductivity in an orientation direction in which the graphite particles (A) are oriented, so that thermal resistance in the orientation direction can be reduced, the thermally conductive sheet preferably contains the graphite particles (A) having a non-spherical shape. Note that only one type of graphite particles (A) may be used, or two or more types of graphite particles (A) may be used in combination.

The graphite particles (A) having a non-spherical shape have a shape that is not particularly limited. For example, the shape can be a plate-like shape such as a scale-like shape or a flaky shape; a spheroidal shape; a needle shape; a rod shape; a fibrous shape; or an irregular shape. Among these, the shape of the graphite particles (A) having a non-spherical shape is more preferably a plate-like shape such as a scale-like shape or a flaky shape, from the following viewpoint: with a plate-like shape, the graphite particles (A) can be easily oriented and also can maintain a contact between particles, and this makes it possible to further improve the thermal conductivity in the orientation direction, so that the thermal resistance in the orientation direction can be further reduced.

In the present specification, “spherical shape” means a perfectly spherical shape or a spheroidal shape having an aspect ratio of 1.0 to 1.5, in other words, a perfectly spherical shape having an aspect ratio of 1.0 or a spheroidal shape having an aspect ratio of more than 1.0 and not more than 1.5, and does not necessarily need to be a perfectly spherical shape. Note that the aspect ratio in a case where the graphite particles (A) have a “spherical shape” means a ratio denoted by the major axis/the minor axis. Further, “non-spherical shape” means a shape different from the “spherical shape”, i.e., a shape having an aspect ratio of more than 1.5. Note that “spheroidal shape” means an ellipsoidal shape obtained by rotating an ellipse, such as the shape of a rugby ball.

In the graphite particles (A) having a “non-spherical shape”, the aspect ratio means a ratio of a maximum length to a minimum length (maximum length/minimum length) of the graphite particles (A). For example, in a case where the shape is a plate-like shape, the aspect ratio is a ratio of the maximum length to a thickness (maximum length/thickness) of the graphite particles (A). The aspect ratio can be determined by: observing a sufficient number of (e.g., not less than 10) graphite particles (A) with use of a scanning electron microscope; calculating the major axis/the minor axis or the maximum length/the minimum length of each of the graphite particles (A); and obtaining, as the aspect ratio, an average value of calculated values of the major axis/the minor axis or calculated values of the maximum length/the minimum length.

In a case where two or more types of graphite particles (A) are used, the aspect ratio is an average aspect ratio calculated by performing weighted average calculation on aspect ratios of the respective types of graphite particles (A).

The aspect ratio of the graphite particles (A) is preferably not less than 20, more preferably not less than 40, and even more preferably not less than 70, from the viewpoint of improving the thermal conductivity in the orientation direction. Although an upper limit of the aspect ratio is not particularly limited, the aspect ratio is normally not more than 1000. In a case where the graphite particles (A) have an aspect ratio of not less than 20, the thermal conductivity in the thickness direction of the thermally conductive sheet can be improved by orienting the graphite particles (A) in the thickness direction of the thermally conductive sheet. This can consequently further reduce the thermal resistance in the thickness direction of the thermally conductive sheet. Thus, an aspect ratio of not less than 20 is preferable.

Examples of the graphite particles (A) used in an embodiment of the present invention include particles of scale-like graphite, scaly graphite, earthy graphite, artificial graphite, flaky graphite, acid-treated graphite, expanded graphite, or carbon fiber flakes.

The graphite particles (A) have an average particle size of preferably 20 μm to 1,000 μm, more preferably 30 μm to 500 μm, and particularly preferably 40 μm to 240 μm. Note here that the average particle size of the graphite particles (A) is a value determined by a laser diffraction/scattering particle size distribution analyzer (LA-920, manufactured by HORIBA, Ltd.).

In a case where the graphite particles (A) have an average particle size of not less than 20 μm, it is easy for the graphite particles (A) to be oriented in a desired direction in the thermally conductive sheet to form a good heat transfer path. Further, in a case where an upper limit of the average particle size of the graphite particles (A) is in the above-described range, the graphite particles are exposed on a surface of the thermally conductive sheet. This allows heat transfer from a heat-generating body to the thermally conductive sheet to be better when the thermally conductive sheet is brought into contact with the heat-generating body.

Further, the graphite particles (A) having a plate-like shape have an average thickness of preferably 0.01 μm to 10 μm, more preferably 0.1 μm to 5 μm, and particularly preferably 0.3 μm to 3 μm. Note here that the average thickness of the graphite particles (A) can be determined by: observing a sufficient number of (e.g., not less than 10) graphite particles (A) with use of an ultra-high resolution scanning electron microscope (S-4800, manufactured by Hitachi, Ltd.); calculating respective thicknesses of the graphite particles (A); and obtaining the average thickness as an average value of the respective thicknesses.

In a case where a lower limit of the average thickness of the graphite particles (A) is in the above-described range, thermal transport quantity per particle becomes large, so that a good heat transfer path can be easily formed. Meanwhile, in a case where an upper limit of the average thickness of the graphite particles (A) is in the above-described range, the number of graphite particles (A) per unit weight increases. Then, the graphite particles (A) interfere with each other. This allows the graphite particles (A) to be oriented in a desired direction, so that a good heat transfer path can be easily formed.

In a case where a degree of orientation of the graphite particles (A) is high to some extent in the thermally conductive sheet in accordance with an embodiment of the present invention, the graphite particles (A) are suitably oriented in the thickness direction of the thermally conductive sheet. As a result, the thermally conductive sheet has a reduced thermal resistance and exhibits superior thermal conductivity.

In contrast, in a case where the degree of orientation of the graphite particles (A) is low to some extent in the thermally conductive sheet, the orientation of the graphite particles (A) is disordered to some extent. Thus, in a case where the degree of orientation of the graphite particles (A) is low to some extent, the thermally conductive sheet easily conforms to the adherend when force is applied during the temporary attachment. Further, force is applied also when the thermally conductive sheet is bonded, by heating, to an adherend such as a heat-generating body and a heat sink. At the time of this application of force, in a case where the degree of orientation of the graphite particles (A) is low to some extent, the thermally conductive sheet easily conforms to the adherend. As described above, in the thermally conductive sheet, in a case where the degree of orientation of the graphite particles (A) is low to some extent, the thermally conductive sheet exhibits a superior temporary attachment property and superior adhesion.

Examples of an index that represents the degree of orientation of the graphite particles (A) include a (110) plane orientation degree of the graphite particles and a (002) plane orientation degree of the graphite particles, which are calculated by a lotgering method with use of an X-ray diffraction profile. Hereinafter, the “(110) plane orientation degree of the graphite particles calculated by a lotgering method with use of an X-ray diffraction profile” will be simply referred to as the “(110) plane orientation degree of the graphite particles”. Further, the “(002) plane orientation degree of the graphite particles calculated by a lotgering method with use of an X-ray diffraction profile” will be simply referred to as the “(002) plane orientation degree of the graphite particles”. A method for obtaining the X-ray diffraction profile is not particularly limited and can be a method in which a commercially available X-ray diffraction device is used, and more specifically, can be a method described in Examples. A method for calculating the (110) plane orientation degree of the graphite particles and the (002) plane orientation degree of the graphite particles is not particularly limited, and can be, for example, a method described in Examples.

From the viewpoint of exhibiting the superior thermal conductivity described above, the (110) plane orientation degree of the graphite particles is preferably not less than 0.010, more preferably not less than 0.020, and even more preferably not less than 0.032. In addition, from the viewpoint of exhibiting the superior temporary attachment property and the superior adhesion which are described above, the (110) plane orientation degree of the graphite particles is preferably less than 0.081, more preferably less than 0.065, and even more preferably less than or not more than 0.045.

From the viewpoint of exhibiting the superior thermal conductivity described above, the (002) plane orientation degree of the graphite particles is preferably not less than −0.10, more preferably not less than 0.00, and even more preferably not less than 0.10. In addition, from the viewpoint of exhibiting the superior temporary attachment property and the superior adhesion which are described above, the (002) plane orientation degree of the graphite particles is preferably not more than 0.50, more preferably not more than 0.40, and even more preferably not more than 0.35.

Further, examples of another index that represents the degree of orientation of the graphite particles (A) include an orientation degree of the graphite particles calculated by Expression (1) below with use of an X-ray diffraction profile. Hereinafter, the “orientation degree of the graphite particles calculated by Expression (1) below with use of an X-ray diffraction profile” may also be referred to as “orientation degree A of graphite particles”.

The orientation degree of the graphite particles=[total vertical count+(total oblique count/2)]/horizontal count (1),

where: the total vertical count is a total of a (100) plane orientation degree and the (110) plane orientation degree; the total oblique count is a total of the (101) plane orientation degree and the (112) plane orientation degree; and the horizontal count is the (002) plane orientation degree.

A method for obtaining the X-ray diffraction profile can be a method similar to the method for obtaining an X-ray diffraction profile that is used to calculate the (110) plane orientation degree of the graphite particles. A method for measuring degrees of orientation in the Expression (1) with use of the X-ray diffraction profile and calculate the total vertical count, the total oblique count, and the horizontal count with use of the degrees s of orientation is not particularly limited. The method can be a method described in Examples.

From the viewpoint of exhibiting the superior thermal conductivity described above, the orientation degree A of the graphite particles is preferably not less than 0.10, more preferably not less than 0.15, and even more preferably not less than 0.20. In addition, from the viewpoint of exhibiting the superior temporary attachment property and the superior adhesion which are described above, the orientation degree A of the graphite particles is preferably less than 0.37, more preferably less than 0.33, and even more preferably less than 0.30.

### (Organic Polymer Compound (B))

In the thermally conductive sheet in accordance with an embodiment of the present invention, the organic polymer compound (B) not only functions as a binder but also makes it possible to improve flexibility of the thermally conductive sheet and allow good adhesion between a heat-generating body and a heat-dissipating body via the thermally conductive sheet.

The organic polymer compound (B) is not particularly limited and can be an organic polymer compound that is ordinarily used in a thermally conductive sheet.

Examples of the organic polymer compound (B) include an acrylic ester-based resin, a resin the main chain of which consists of repeated siloxane bonds (silicone resin), a resin which has rubber elasticity at room temperature (elastomer resin), an epoxy resin, a fluorine resin, polyolefin, polyvinyl chloride, polyvinylidene chloride, polyvinyl acetate, an ethylene-vinyl acetate copolymer, polyvinyl alcohol, polyacetal, polyethylene terephthalate, polybutylene terephthalate, polyethylene naphthalate, polystyrene, polyacrylonitrile, polyphenylene ether, modified polyphenylene ether, aliphatic polyamides, aromatic polyamides, polyamideimide, polycarbonate, polyphenylene sulfide, polysulfone, polyether sulfone, polyether nitrile, polyether ketone, polyketone, polyurethane, a liquid crystal polymer, and an ionomer. One type of these organic polymer compounds may be used alone, or two or more types may be used in combination.

The organic polymer compound (B) may be either solid or liquid at normal temperature. Note that “normal temperature” refers to 20 °C in the present specification.

Respective ranges of a Tg and a weight average molecular weight of the organic polymer compound (B) are preferably the same as preferable ranges of a Tg and a weight average molecular weight of an acrylic ester-based resin which will be described later. This allows the thermally conductive sheet to yield an effect that is similar to an effect obtained in a case where the acrylic ester-based resin has a Tg and a weight average molecular weight in the preferable ranges.

A content of the organic polymer compound (B) relative to the total weight of the thermally conductive sheet is preferably not less than 10% by weight, more preferably not less than 15% by weight, and even more preferably not less than 20% by weight. In a case where the content of the organic polymer compound (B) is not less than 10% by weight, it is possible to improve flexibility of the thermally conductive sheet and cause a heat-generating body and a heat-dissipating body to adhere to each other well via the thermally conductive sheet.

The content of the organic polymer compound (B) relative to the total weight of the thermally conductive sheet is preferably not more than 60% by weight, more preferably not more than 50% by weight, and even more preferably not more than 40% by weight.

### (Acrylic Ester-Based Resin)

The organic polymer compound (B) preferably contains an acrylic ester-based resin. Use of the acrylic ester-based resin advantageously makes it possible to obtain a thermally conductive sheet that has not only adhesiveness but also elasticity with which the thickness of the thermally conductive sheet is restored. As the acrylic ester-based resin, one type of acrylic ester-based resin may be used alone, or two or more types may be used in combination.

The acrylic ester-based resin includes: a polymer of monomer components that contain at least one type of acrylic monomer selected from the group consisting of (meth)acrylic acids and (meth)acrylic esters; and a copolymer of the acrylic monomer and another monomer. Note here that “(meth)acrylic” is intended to include both “methacrylic” and “acrylic” in the present specification. Examples of the (meth)acrylic esters include methyl (meth)acrylate, ethyl (meth)acrylate, n-butyl (meth)acrylate, isobutyl (meth)acrylate, 2-ethylhexyl (meth)acrylate, and cyclohexyl (meth)acrylate.

Examples of the another monomer include acrylonitrile, glycidyl methacrylate, and 2-chloroethylvinyl ether. Note that acrylic rubber is obtained by copolymerizing a (meth)acrylic ester with, for example, acrylonitrile or 2-chloroethylvinyl ether. In the present specification, the acrylic rubber is considered to be included in the acrylic ester-based resin although the acrylic rubber is also classified into elastomer resin, which will be described later.

More preferable examples of the acrylic ester-based resin include an acrylic ester-based resin that contains butyl acrylate and/or 2-ethylhexyl acrylate as a monomer(s), a total amount of which is not less than 50% by weight relative to a total amount of monomer components. The acrylic ester-based resin is preferable because high flexibility can be easily obtained, chemical stability and processability are excellent, and adhesiveness can be easily controlled. Further, in view of long-term adhesion retention and film strength, it is preferable to include, in the acrylic ester-based resin, a crosslinked structure in a range that does not impair flexibility. The crosslinked structure can be included by, for example, reacting a compound having an isocyanate group with a polymer having a hydroxyl group. Alternatively, the crosslinked structure can be included by, for example, reacting a compound having an epoxy group with a polymer having a carboxyl group.

A content of the acrylic ester-based resin relative to the total weight of the organic polymer compound (B) is preferably not less than 15% by weight, more preferably not less than 20% by weight, even more preferably not less than 25% by weight, and particularly preferably not less than 30% by weight. For example, the content of the acrylic ester-based resin can be 100% by weight relative to the total weight of the organic polymer compound (B).

The acrylic ester-based resin has a Tg of preferably not higher than −35 °C, more preferably not higher than −50 °C, and even more preferably not higher than −60 °C. In a case where the acrylic ester-based resin has a Tg of not higher than −35 °C, the acrylic ester-based resin can easily flow when the thermally conductive sheet is bonded in a hot press machine. This allows the thermally conductive sheet to have higher wettability to an adherend bonded thereto and have higher adhesion to the adherend. A lower limit of the Tg of the acrylic ester-based resin is not particularly limited, and is exemplified by not lower than −150 °C. The “Tg” described in the present specification can be calculated by, for example, a method described in Examples.

The acrylic ester-based resin may be either solid or liquid at normal temperature under normal pressure. In particular, the acrylic ester-based resin is preferably liquid at normal temperature under normal pressure.

In the present specification, “normal temperature” refers to 20 °C and “normal pressure” refers to 1 atm. In other words, the acrylic ester-based resin has a melting point of preferably not higher than 20 °C. Note that “melting point” described in the present specification is a melting point under normal pressure (1 atm). Further, in the present specification, “being liquid” means that, when a target resin is held in a container such as a bottle or a can at room temperature (20 °C) and the container is tilted, the resin flows. In addition, the resin may be in the form of a resin lump.

The acrylic ester-based resin has a weight average molecular weight of preferably not less than 50,000, more preferably not less than 150,000, and even more preferably not less than 250,000. In a case where the acrylic ester-based resin has a weight average molecular weight of as high as not less than 50,000, it is difficult for the acrylic ester-based resin to flow when an external force is applied to the thermally conductive sheet (i) during release of a press plate after hot pressing during bonding and (ii) after bonding. This allows the thermally conductive sheet to have higher adhesion to an adherend.

The acrylic ester-based resin has a weight average molecular weight of preferably not more than 3,000,000, more preferably not more than 2,000,000, and even more preferably not more than 1,500,000. In a case where the acrylic ester-based resin has a weight average molecular weight of not more than 3,000,000, the acrylic ester-based resin can easily flow when the thermally conductive sheet is bonded in a hot press machine. This allows the thermally conductive sheet to have higher wettability to an adherend bonded thereto and have higher adhesion to the adherend.

The weight average molecular weight described in the present specification can be measured with use of a calibration curve of standard polystyrene by, for example, gel permeation chromatography of a measurement target object.

The organic polymer compound preferably contains an acrylic ester-based resin having a functional group. In the present specification, the acrylic ester-based resin having a functional group means that an acrylic ester-based resin contains a polymer of monomer components which include a monomer having a functional group.

The functional group has a function of binding the plurality of graphite particles (A). Thus, the acrylic ester-based resin having the functional group makes it possible to form the composition in sheet form, so that a thermally conductive sheet containing the composition can be provided. Further, there is a case where the functional group interacts with a substance of which a surface of an adherend is made, and contributes to adhesion between the thermally conductive sheet and the adherend. In that case, adhesion between the thermally conductive sheet and the adherend is considered to be also improved.

A type of the functional group is not particularly limited provided that the functional group has a function of binding the plurality of graphite particles (A). The functional group may be one type of functional group or two or more types of functional groups. The functional group can be at least one selected from, for example, a hydroxyl group, a carboxyl group, and an epoxy group. The functional group is preferably a hydroxyl group and/or a carboxyl group, and more preferably a hydroxyl group. For example, the type of the functional group can be identified by a known method such as structure analysis which is carried out with respect to the acrylic ester-based resin and in which NMR or the like is used.

The monomer having the functional group is not particularly limited, and preferable examples thereof include 2-hydroxyethyl (meth)acrylate, 3-hydroxypropyl (meth)acrylate, 4-hydroxybutyl (meth)acrylate, 2-hydroxy-1-methyl (meth)acrylate, acrylic acid, methacrylic acid, and glycidyl (meth)acrylate. Among these, the monomer having the functional group more preferably contains 2-ethylhexyl acrylate. In other words, the acrylic ester-based resin more preferably contains a copolymer containing 2-ethylhexyl acrylate as a monomer.

In an embodiment of the present invention, in a case where a content of the functional group relative to a total weight of the acrylic ester-based resin is high, graphite particles (A) more suitably bind to each other via the acrylic ester-based resin in the thermally conductive sheet. As a result, the thermally conductive sheet has higher graphite binding capacity. In the following description, the content of the functional group relative to the total weight of the acrylic ester-based resin is referred to as “content C of a functional group”. Note that the content C of the functional group is a total amount of a content A of a functional group described later and a content B of a functional group described later.

A preferable range of the content C of the functional group is not less than 0.001 mmol/g, and not more than 0.410 mmol/g. The preferable range of the content C of the functional group can vary in accordance with, for example, a type of the functional group and a type of the graphite particles (A). For example, in a case where the functional group is at least one selected from a hydroxyl group, a carboxyl group, and an epoxy group, the content C of the functional group is preferably not less than 0.001 mmol/g, more preferably not less than 0.010 mmol/g, and even more preferably not less than 0.090 mmol/g from the viewpoint of further improving the graphite binding capacity. The content of the functional group can be expressed not only in a unit of “mmol/g” but also in a unit of “KOH mg/g”, which is commonly used. Specifically, for example, in a case where the functional group is at least one selected from a hydroxyl group, a carboxyl group, and an epoxy group, the content C of the functional group is preferably not less than 0.056 KOH mg/g, more preferably not less than 0.56 KOH mg/g, and even more preferably not less than 5.05 KOH mg/g.

The functional group can also ordinarily form a bond with a water molecule. Thus, in a case where the content C of the functional group is in a range of not more than a predetermined value, the affinity of the acrylic ester-based resin to water is reduced, so that moisture absorbency is also reduced. As a result, in the thermally conductive sheet, the moisture absorbency is controlled in a suitable range, so that the thermally conductive sheet has further improved adhesion after maintained at high temperature.

For example, in a case where the functional group is a hydroxyl group, from the viewpoint of further improving the adhesion after maintaining the thermally conductive sheet at high temperature, the content C of the functional group is preferably not more than 0.371 mmol/g, more preferably not more than 0.340 mmol/g, and even more preferably not more than 0.300 mmol/g. In a case where the functional group is a hydroxyl group and the content C of the functional group is expressed in the unit of “KOH mg/g”, the content C of the functional group is preferably not more than 20.76 KOH mg/g, more preferably not more than 19.08 KOH mg/g, and even more preferably not more than 16.83 KOH mg/g.

For example, in a case where the functional group is a carboxyl group, from the viewpoint of further improving the adhesion after maintaining the thermally conductive sheet at high temperature, the content C of the functional group is preferably not more than 0.410 mmol/g, more preferably not more than 0.360 mmol/g, and even more preferably not more than 0.300 mmol/g. In a case where the functional group is a carboxyl group and the content C of the functional group is expressed in the unit of “KOH mg/g”, the content C of the functional group is preferably not more than 23.00 KOH mg/g, more preferably not more than 20.20 KOH mg/g, and even more preferably not more than 16.83 KOH mg/g.

Note that conversion from mmol/g to KOH mg/g is calculated by multiplying mmol/g by 56.1056 mg/mmol.

A method for measuring the content C of the functional group is exemplified by, but not particularly limited to, a method including steps (1) to (3) below.

(1) A known method is used to extract the acrylic ester-based resin from the thermally conductive sheet and measure a total weight (unit: g) of the extracted acrylic ester-based resin.
(2) ¹HNMR or the like is used to measure a substance amount (unit: mmol) of the functional group in the acrylic ester-based resin extracted in step (1).
(3) The content (unit: mmol/g) of the functional group is calculated by dividing, by the total weight of the acrylic ester-based resin which total weight has been measured in step (1), the substance amount of the functional group in the acrylic ester-based resin which substance amount has been measured in step (2).

Assume a in which weight average case molecular weights of all polymers contained in the acrylic ester-based resin, a content of a monomer having the functional group in all monomers constituting the polymers, and a content ratio of each of the polymers are known. In this case, on the basis of those, the content C of the functional group can also be calculated.

The acrylic ester-based resin more preferably contains an acrylic resin having a functional group and/or an acryl block copolymer. More specifically, the organic polymer compound (B) preferably contains an acrylic resin having a functional group or an acryl block copolymer, and more preferably contains an acrylic resin having a functional group and an acryl block copolymer. The acrylic resin having the functional group may be composed of one type of acrylic resin having a functional group or may be a mixture of two or more types of acrylic resins having a functional group. The acryl block copolymer may be composed of one type of acryl block copolymer or may be a mixture of two or more types of acryl block copolymers.

### <Acrylic Resin Having Functional Group>

The acrylic resin having the functional group has a glass transition temperature (Tg) of preferably not higher than −35 °C, more preferably not higher than −50 °C, and even more preferably not higher than −60 °C. In a case where the acrylic resin having the functional group has a Tg of not higher than −35 °C, the acrylic ester-based resin can easily flow when the thermally conductive sheet is bonded in a hot press machine. This allows the thermally conductive sheet to have higher wettability to an adherend bonded thereto and have higher adhesion to the adherend. A lower limit of the Tg of the acrylic resin having the functional group is not particularly limited, and is exemplified by not lower than −150 °C.

The acrylic resin having the functional group has a weight average molecular weight of preferably not less than 100,000, more preferably not less than 300,000, and even more preferably not less than 500,000. Further, the acrylic resin having the functional group has a weight average molecular weight of preferably not more than 3,000,000, more preferably not more than 2,000,000, and even more preferably not more than 1,500,000. The weight average molecular weight of the acrylic ester-based resin can be suitably controlled in the above-described preferable range by adjusting the weight average molecular weight of the acrylic resin having the functional group in the above-described preferable range described above. The acrylic resin having the functional group has a molecular weight distribution (weight average molecular weight/number average molecular weight) of preferably 1.0 to 10.0.

The acrylic resin having the functional group may be either solid or liquid at normal temperature under normal pressure, and is preferably liquid. In other words, the acrylic resin having the functional group is preferably an acrylic resin having a functional group whose melting point is not higher than 20 °C.

The acrylic resin having the functional group preferably has not less than 50% by weight of a repeating unit derived from an acrylic monomer. The acrylic resin having the functional group includes a polymer at least some of monomers of which have the functional group and a monomer component of which contains at least one type of acrylic monomer. It is possible to employ, as the acrylic monomer and the another monomer, the acrylic monomer and another monomer which are described earlier as monomers that can constitute the acrylic ester-based resin.

Further, the percentage of the weight of the monomer having the functional group to the weight of all monomers constituting the acrylic resin having the functional group is preferably 0.1% by weight to 5.2% by weight, and more preferably 0.3% by weight to 4.0% by weight. Further, the percentage of the substance amount of the monomer having functional group to the substance amount of all the monomers constituting the acrylic resin is preferably 0.1 mol % to 5.0 mol %, and more preferably 0.3 mol % to 4.0 mol %. It is preferable to adjust the above percentages in the ranges described later in order to suitably control the content of the functional group in the acrylic resin having the functional group in the above-described range. It is possible to employ, as the monomer having the functional group, the monomers having a functional group which are described above as a monomer that can constitute the acrylic ester-based resin. In the following description, the content of the functional group relative to the weight of the acrylic resin having the functional group is referred to as “content A of the functional group”.

From a viewpoint of further improving the graphite binding capacity, the content A of the functional group is preferably not less than 0.010 mmol/g, and more preferably not less than 0.050 mmol/g, relative to the total weight of the acrylic resin having the functional group.

Further, when the thermally conductive sheet is maintained in a high-temperature environment and heat is applied, water that has been absorbed is discharged to the outside by the heat. In accordance with this, the shape of the thermally conductive sheet changes. This may reduce adhesion to an adherend after the thermally conductive sheet is maintained at high temperature. Specifically, it is considered that a thermally conductive sheet containing an acrylic ester-based resin having high moisture absorbency may be in a state in which a large amount of water is absorbed from the air. In that case, it is inferred that a large amount of water discharged increases a degree of the aforementioned change in shape, so that adhesion to the adherend tends to decrease due to formation of a gap between the thermally conductive sheet and the adherend. Then, it is considered that a thermally conductive sheet which has excellent adhesion to an adherend after maintained at high temperature can be achieved in a case where the acrylic ester-based resin is poorly water-soluble.

Note here that in an embodiment of the present invention, in a case where the content A of the functional group is low, the functional group can normally react with a water molecule (H₂O). Accordingly, the acrylic ester-based resin has a lower affinity for water and has a lower moisture absorbency. As a result, in the thermally conductive sheet, the moisture absorbency is controlled in a suitable range, so that the thermally conductive sheet has further improved adhesion after maintained at high temperature.

Specifically, for example, in a case where the functional group is a hydroxyl group, the content A of the functional group is preferably not more than 0.371 mmol/g, more preferably not more than 0.340 mmol/g, and even more preferably not more than 0.300 mmol/g, relative to the total weight of the acrylic resin having the functional group, from the viewpoint of improving adhesion after maintaining the thermally conductive sheet at high temperature.

Further, for example, in a case where the functional group is a carboxyl group, the content A of the functional group is preferably not more than 0.410 mmol/g, more preferably not more than 0.360 mmol/g, and even more preferably not more than 0.300 mmol/g, relative to the total weight of the acrylic resin having the functional group, from the viewpoint of improving the adhesion.

In a case where the content A of the functional group is in the above-described range, it is possible to suitably control, in a preferable range, the content C of the above-described functional group. Note that a method for measuring the content A of the functional group can be a method identical to, for example, the method for measuring the content C of the functional group except that the acrylic resin having the functional group is targeted.

The acrylic resin having the functional group may include a random copolymer or a block copolymer. Note, however, that the random copolymer is more preferable due to its availability. The acrylic resin having the functional group may have a linear or branched structure. Note, however, that a linear structure is more preferable due to its availability.

### <Acryl Block Copolymer>

The acryl block copolymer has a block structure and thus has Tg at a low temperature and a high temperature. Since the acryl block copolymer has Tg at a low temperature, the thermally conductive sheet containing the acryl block copolymer has flexibility even at low temperature. Thus, the thermally conductive sheet containing the acryl block copolymer can have adhesion even in a case where the thermally conductive sheet is exposed to low temperature. Further, as the acryl block copolymer has Tg at a high temperature, the thermally conductive sheet containing the acryl block copolymer does not become too soft even at high temperature but has elasticity. Thus, the thermally conductive sheet containing the acryl block copolymer can have adhesion even in a case where the thermally conductive sheet is exposed to high temperature. The thermally conductive sheet therefore has excellent adhesion after maintained at high temperature.

The Tg of the acryl block copolymer on a low-temperature side is preferably not higher than −35 °C, and more preferably not higher than −50 °C. In a case where the Tg of the acryl block copolymer on the low-temperature side is not higher than −35 °C, the acrylic ester-based resin can easily flow when the thermally conductive sheet is bonded in a hot press machine. This allows the thermally conductive sheet to have higher wettability to an adherend bonded thereto and have higher adhesion to the adherend. A lower limit of the Tg of the acryl block copolymer on the low-temperature side is not particularly limited, and is exemplified by not lower than −150 °C and preferably not lower than −55 °C.

A lower limit of the Tg of the acryl block copolymer on a high-temperature side is exemplified by preferably not lower than 100 °C and more preferably not lower than 102 °C. Further, an upper limit of the Tg of the acryl block copolymer on the high-temperature side is exemplified by preferably not higher than 120 °C and more preferably not higher than 118 °C. In a case where the Tg on the high-temperature side is in the above-described range, it is possible to more suitably prevent the thermally conductive sheet from being excessively soft at high temperature and more suitably retain elasticity at high temperature. As a result, adhesion after maintaining the thermally conductive sheet at high temperature can be further improved.

The acryl block copolymer has a weight average molecular weight of preferably not less than 10,000, more preferably not less than 30,000, and even more preferably not less than 50,000. Further, the acryl block copolymer has a weight average molecular weight of preferably not more than 3,000,000, more preferably not more than 2,000,000, and even more preferably not more than 1,500,000. The weight average molecular weight of the acrylic ester-based resin can be suitably controlled in a preferable range which will be described later, by adjusting the weight average molecular weight of the acryl block copolymer in the above-described preferable range. The acryl block copolymer has a molecular weight distribution (weight average molecular weight/number average molecular weight) of preferably 1.0 to 2.0.

The acryl block copolymer may be either solid or liquid at normal temperature under normal pressure, and is preferably liquid. In other words, preferably, the acryl block copolymer has a melting point of not higher than 20 °C.

The acryl block copolymer preferably has not less than 50% by weight of a repeating unit derived from an acrylic monomer. The acryl block copolymer includes a copolymer of monomer components that contain two or more types of acrylic monomers. The acryl block copolymer also includes a copolymer of at least one type of acrylic monomer and at least one type of another monomer. It is possible to employ, as the acrylic monomer and the another monomer, the acrylic monomer and another monomer which are described earlier as monomers that can constitute the acrylic ester-based resin.

The acryl block copolymer is a block copolymer. Note here that the “block copolymer” means a polymer in which a most part of a main chain, preferably a whole of a main chain, has a structure where blocks having two or more different types of chemical structures are linked to each other. Such a block is composed of repeating units that are derived from two or more monomers. The “most part of a main chain” means a part constituted by, for example, not less than 95% and preferably not less than 97% of the total number of repeating units derived from monomers constituting the main chain.

Examples of the block structure of the acryl block copolymer include a di-block (A-B), a tri-block (A-B-A or A-B-C), and a tetra-block (A-B-A-B, A-B-C-D, or the like). It is preferable to have an A-B-A triblock copolymer, from the viewpoint of improving adhesion at high temperature.

Repeating units constituting a block A of the A-B-A triblock copolymer are preferably derived from monomers, such as a methyl methacrylate, with which a homopolymer has a Tg in a range of 100 °C to 120 °C or higher. Repeating units constituting a block B are preferably derived from monomers, such as butyl acrylate and 2-ethylhexyl acrylate, with which a homopolymer has a Tg in a range of −60 °C to −40 °C or lower. Preferable examples of the A-B-A triblock copolymer include poly(methyl methacrylate)-poly(butyl acrylate)-poly(methyl methacrylate), poly(methyl methacrylate)-poly(2-ethylhexyl acrylate)-poly(methyl methacrylate), and poly(methyl methacrylate)-random poly(butyl acrylate, 2-ethylhexyl acrylate)-poly(methyl methacrylate).

The A-B-A triblock copolymer has blocks whose weigh ratio is preferably A/B/A=1 to 25/98 to 50/1 to 25. The A-B-A triblock copolymer has a weight average molecular weight of preferably 10,000 to 3,000,000.

The acryl block copolymer may have a functional group. A type of the functional group is not particularly limited. The functional group can be at least one selected from, for example, a hydroxyl group, a carboxyl group, and an epoxy group. The type of the functional group is preferably a hydroxyl group and/or a carboxyl group, and more preferably a hydroxyl group. Meanwhile, the functional group can normally react with a water molecule (H₂O). Thus, in a case where the content of the functional group is low, and preferably in a case where the acryl block copolymer does not have the functional group, the acrylic ester-based resin has a low affinity for water and has a low moisture absorbency. As a result, as in the above-described case in which the content A of the functional group is low, in the thermally conductive sheet, the moisture absorbency is controlled in a suitable range, so that the thermally conductive sheet has further improved adhesion after maintained at a high temperature. From the above-described viewpoint, the content of the functional group in the acryl block copolymer is preferably low.

In the following description, the content of a functional group relative to the weight of the acryl block copolymer is referred to as “content B of the functional group”. Specifically, the content B of the functional group is preferably not more than 0.020 mmol/g, and more preferably less than 0.010 mmol/g, relative to the total weight of the acryl block copolymer. Note that the content B of the functional group is particularly preferably 0 mmol/g, that is, particularly preferably, the acryl block copolymer does not have the functional group. Note that a method for measuring the content B of the functional group can be same as, for example, the above-described method for measuring the content C of the functional group except that the acryl block copolymer is targeted.

Further, the acryl block copolymer having a low content t of the functional group has high heat resistance. This acryl block copolymer has a structure that has higher stability against heat. Thus, when heat is applied, the acryl block copolymer having a low content of the functional group is less likely to generate a radical than an acryl block copolymer having a high content of the functional group. Thus, in a case where the content B of the functional group is low, the acrylic ester-based resin generates a smaller amount of radicals when heat is applied than in a case where the content B of the functional group is high. Accordingly, in a case where the content B of the functional group is low in the thermally conductive sheet containing the acrylic ester-based resin, it is difficult for a chain reaction to proceed. As a result, in a case where the content B of the functional group is low, tackiness of the acrylic ester-based resin is less likely to lower when heat is applied. Thus, the thermally conductive sheet has excellent tackiness after maintained at high temperature.

In the following description, a ratio of the weight of the acrylic resin having the functional group to the weight of the acryl block copolymer in the acrylic ester-based resin (the acrylic resin having the functional group/the acryl block copolymer) will be referred to as “ratio A”. Having a ratio A of not less than a predetermined value means that in the acrylic ester-based resin, the content of the acrylic resin having the functional group and the content of the functional group are suitably high. In that case, the graphite binding capacity of the thermally conductive sheet that is caused by the presence of the functional group is further improved. From the viewpoint of further improving the graphite binding capacity of the thermally conductive sheet, the ratio A is preferably not less than 0.02, more preferably not less than 0.05, and even more preferably not less than 0.1.

Having the ratio A of not more than a predetermined value means that in the acrylic ester-based resin, the content of the acryl block copolymer is suitably high. In that case, the adhesion of the thermally conductive sheet having been maintained at high temperature is further improved. This adhesion is caused by the presence of the acryl block copolymer. From the viewpoint of further improving the adhesion after maintaining the thermally conductive sheet at high temperature, the ratio A is preferably not more than 50, more preferably not more than 25, and even more preferably not more than 10.

Note that from the viewpoint improving the graphite binding capacity of the thermally conductive sheet and the adhesion after maintaining the thermally conductive sheet at high temperature in a balanced manner, the ratio A is preferably in the above-described range, more preferably 1.2 to 8, and particularly preferably 1.5 to 5.

### (Composition)

The composition may contain, if necessary, at least one type of additive(s) such as a plasticizer, a flame retardant, an anti-aging agent, a thermal stabilizer, a colorant, an antistatic agent, a tackifier, and/or a filler that is different from the graphite particles (A). The composition preferably contains an anti-aging agent and/or a tackifier. The composition containing the additive(s) means that the thermally conductive sheet of an aspect of the present invention further contains the additive(s). Note that in a method for producing a thermally conductive sheet in accordance with an embodiment of the present invention, which will be described later, a mixture containing the graphite particles (A), the organic polymer compound (B), and a solvent is used to form a primary sheet. In the present specification, the “composition” means, rather than the mixture, a composition obtained after a solvent is removed by, for example, drying, that is, a composition contained in a thermally conductive sheet that is finally obtained.

The plasticizer can be, for example, polybutene and/or a phosphorus-based flame retardant. In a case where the thermally conductive sheet contains polybutene and/or a phosphorus-based flame retardant, an effect of improving wettability to silicon and/or a spreader and reducing thermal resistance is exhibited. The flame retardant can be, for example, a phosphorus-based flame retardant. A phosphorus-based flame retardant has a function of preventing or reducing burning of a resin.

In an embodiment of the present invention, in a case where the composition contains a plasticizer, a content of the plasticizer is preferably not more than 20% by weight relative to the total weight of the solid content of the composition. The total weight of the solid content of the composition corresponds to the total weight of the thermally conductive sheet in accordance with an embodiment of the present invention.

Examples of the anti-aging agent include a phenol-based anti-aging agent and an amine-based anti-aging agent. An amount of the anti-aging agent mixed is preferably 0.1 parts by weight to 10 parts by weight, and more preferably 0.2 parts by weight to 8 parts by weight, relative to a total weight of 100 parts by weight of the organic polymer compound (B).

In an embodiment of the present invention, the content of the graphite particles (A) in the composition is preferably 30% by weight to 80% by weight, more preferably 35% by weight to 75% by weight, and even more preferably 40% by weight to 70% by weight, relative to the total weight of the composition. A content of not less than 30% by weight of the graphite particles (A) is preferable because sufficient thermal conductivity is exhibited. Further, a content of not more than 80% by weight of the graphite particles (A) is preferable because flexibility and adhesion become excellent.

In an embodiment of the present invention, the content of the organic polymer compound (B) in the composition is preferably 10% by weight to 60% by weight, more preferably 15% by weight to 50% by weight, and even more preferably 20% by weight to 40% by weight, relative to the total weight of the composition. In a case where the content of the organic polymer compound (B) is not less than 10% by weight, it is possible to improve flexibility of the thermally conductive sheet and allow for good adhesion between a heat-generating body and a heat-dissipating body via the thermally conductive sheet. Thus, the content of the organic polymer compound (B) is preferably not less than 10% by weight. A higher content of the organic polymer compound (B) in a range of not more than 60% by weight is preferable because the graphite particles (A) can be suitably immobilized, and higher adhesion between the thermally conductive sheet and the semiconductor and/or the spreader is achieved.

### [1-3. Thermally Conductive Sheet]

### (Orientation of Graphite Particles (A))

The graphite particles (A) are oriented in the thickness direction of the thermally conductive sheet. In a case where the graphite particles (A) are oriented in the thickness direction of the thermally conductive sheet, the thermal conductivity in the thickness direction in which the graphite particles (A) are oriented can be improved. This can reduce thermal resistance in the thickness direction in which the graphite particles (A) are oriented. Thus, it is preferable that the graphite particles (A) be oriented in the thickness direction. Note that not all the graphite particles (A) contained in the thermally conductive sheet need to be oriented in the thickness direction of the thermally conductive sheet, provided that the thermal conductivity in the thickness direction in which the graphite particles (A) are oriented can be improved.

The expression “graphite particles (A) being oriented in the thickness direction of the thermally conductive sheet” means that an angle of a six-membered carbon ring plane in a crystal of the graphite particles (A) relative to a sheet surface of the thermally conductive sheet is more than 45°. The angle is more preferably not less than 50°, even more preferably not less than 70°, and particularly preferably not less than 80°. Note that the “angle of the six-membered carbon ring plane relative to the sheet surface of the thermally conductive sheet” is intended to mean a smaller one of two angles formed between the six-membered carbon ring plane and the sheet surface of the thermally conductive sheet, except for a case where the two angles are 90°. In the graphite particles (A), the six-membered carbon ring plane in the crystal of the graphite particles (A) is oriented in a surface direction of a scale or a flake in the case of the graphite particles (A) having a plate-like shape such as a scale-like shape or a flaky shape, and is oriented in a major axis direction of particles in the case of the graphite particles (A) having a spheroidal shape, a needle shape, a rod shape, a fibrous shape, or an irregular shape. Note that a direction of the major axis of the graphite particles (A) matches a direction of the maximum length of the graphite particles (A).

The angle of the six-membered carbon ring plane in the crystal of the graphite particles (A) relative to the sheet surface, which is a surface of the thermally conductive sheet, can be measured by using a scanning electron microscope to observe a cross section of the thermally conductive sheet in the thickness direction. First, a thin film section of a central part of the thermally conductive sheet in the thickness direction is produced. Then, the scanning electron microscope is used to observe the graphite particles (A) in the thin film section and measure an angle formed between the major axis of any 20 graphite particles (A) and the sheet surface, so that the angle of the six-membered carbon ring plane in the crystal of the graphite particles (A) to the sheet surface can be determined. In the present specification, the above-described angles of not less than 45°, not less than 50°, not less than 70°, and not less than 80° each mean that an average of values measured as described above is not less than a corresponding angle. In a case where an angle formed between the major axis of the graphite particles (A) and the sheet surface is more than 90°, a supplementary angle to the angle is regarded as a measurement value.

(Physical Properties Etc. Of Thermally Conductive Sheet)

The thermally conductive sheet in accordance with an embodiment of the present invention has a thermal resistance of preferably not more than 0.20 °C/W, more preferably not more than 0.12 °C/W, even more preferably not more than 0.10 °C/W, and particularly preferably not more than 0.085 °C/W. Note here that in the present specification, thermal resistance refers to thermal conduction in the thickness direction of the thermally conductive sheet and refers to a thermal resistance value measured by a method described in Examples. In a case where the thermal resistance is not more than 0.20 °C/W, the thermally conductive sheet has excellent thermal conductivity and has excellent heat dissipation characteristics when the thermally conductive sheet is interposed between a heat-generating body and a heat-dissipating body and used as a heat dissipation device. The thermal resistance that is lower is preferable.

The thermally conductive sheet in accordance with an embodiment of the present invention has a thickness of preferably not more than 500 μm, more preferably not more than 200 μm, even more preferably not more than 140 μm, still more preferably 100 μm, still more preferably not more than 95 μm, and particularly preferably not more than 80 μm. Note here that in the present specification, the “thickness of the thermally conductive sheet” refers to a thickness measured by a method described in Examples. The thermally conductive sheet that has a thickness of not more than 500 μm is preferable because such a thermally conductive sheet can be attached to a heat-generating body such as an electronic component even in a narrow space. As long as the thermally conductive sheet exhibits a function as a thermally conductive sheet, the thickness of the thermally conductive sheet has a lower limit that is not particularly limited and that is preferably not less than 3 μm, and more preferably not less than 5 μm.

The thermally conductive sheet in accordance with an embodiment of the present invention has a hardness of preferably not less than 65, more preferably not less than 70, even more preferably not less than 75, and particularly preferably 80, at 20 °C. Note here that in the present specification, the “hardness at 20 °C of the thermally conductive sheet” refers to a hardness measured by a method described in Examples. The thermally conductive sheet that has a hardness of not less than 65 at 20 °C is preferable because such a thermally conductive sheet is sufficiently hard and thus can be sliced to have a small thickness. The thermally conductive sheet has a hardness of preferably not more than 95, more preferably not more than 90, and even more preferably not more than 88, at 20 °C. The thermally conductive sheet that has a hardness of not more than 95 at 20 °C allows sufficient adhesion of the thermally conductive sheet to a component with which the thermally conductive sheet is in contact. It is therefore possible to successfully transfer heat and sufficiently relax thermal stress.

The thermally conductive sheet in accordance with an embodiment of the present invention has a hardness of preferably more than 60, more preferably not less than 63, and even more preferably not less than 65, at 70 °C. Note here that in the present specification, the “hardness at 70 °C of the thermally conductive sheet” refers to a hardness measured by a method described in Examples. The thermally conductive sheet that has a hardness of more than 60 at 70 °C is preferable because such a thermally conductive sheet is sufficiently hard and thus can be sliced to have a small thickness. The thermally conductive sheet has a hardness of preferably not more than 90, more preferably not more than 85, and even more preferably not more than 83, at 70 °C. The thermally conductive sheet that has a hardness of not more than 90 at 70 °C allows for sufficient adhesion of the thermally conductive sheet to a component with which the thermally conductive sheet is in contact. It is therefore possible to successfully transfer heat and sufficiently relax thermal stress.

The temporary attachment property of the thermally conductive sheet in accordance with an embodiment of the present invention can be evaluated by: peeling a 40 mm×40 mm sized piece of the thermally conductive sheet off from a separator (backing sheet); and bonding this piece of the thermally conductive sheet to a 50 mm×50 mm piece of a silicon wafer. The excellent temporary attachment property of the thermally conductive sheet means the following:
The thermally conductive sheet is easily peeled off from the separator.
The thermally conductive sheet can be fixed and bonded accurately on the silicon wafer.
Even in a case where the silicon wafer is transported or turned upside down, the thermally conductive sheet does not peel off.
The air entrained between the silicon wafer and the thermally conductive sheet is easily released.

The initial adhesion of the thermally conductive sheet in accordance with an embodiment of the present invention, the adhesion after maintaining the thermally conductive sheet at high temperature, and the adhesion after heat cycles can be evaluated by a method described in Examples, which will be described later. It is preferable that results of such evaluation for all of those adhesions be A or B on the basis of criteria described in Examples, which will be described later.

### [1-4. Method for Producing Thermally Conductive Sheet]

A method for producing a thermally conductive sheet in accordance with an embodiment of the present invention is not particularly limited provided that it possible to produce, by the method, a thermally conductive sheet having the tensile strength (X) and the tensile strength (Y) that are controlled in ranges which satisfy the feature A. Examples of such a production method include a production method that includes: a primary sheet forming step of forming, in sheet form, a mixture containing graphite particles (A), an organic polymer compound (B), and a solvent, to obtain a primary sheet in which the graphite particles (A) are oriented in a direction parallel to a sheet surface; a laminate forming step of layering the primary sheet to obtain a primary sheet laminate; and a slicing step of slicing a multilayer cross section of the primary sheet laminate to obtain a thermally conductive sheet.

The production method configured as above makes it possible to control, in suitable ranges, the tensile strength (X) and the tensile strength (Y), and produce the thermally conductive sheet in accordance with an embodiment of the present invention.

### (Primary Sheet Forming Step)

In the primary sheet forming step, a mixture containing graphite particles (A), an organic polymer compound (B), and a solvent is formed in sheet form to obtain a primary sheet in which the graphite particles (A) are oriented in a direction parallel to a sheet surface.

Note here that the graphite particles (A), the organic polymer compound (B), and a composition containing the graphite particles (A) and the organic polymer compound (B) are as described in the above section [1-2.].

Conventionally known as a method for the primary sheet forming step is a method in which a primary sheet is obtained by: melt-kneading the graphite particles (A), the organic polymer compound (B), and, if necessary, the above-described additive(s) without adding a solvent; and forming a resultant kneaded product in sheet form. According to a result of verification by the inventors of the present invention, the thermally conductive sheet produced with use of a primary sheet that has been obtained by the method was not controlled so as to have the tensile strength (X) and the tensile strength (Y) in ranges that satisfy the feature A. In light of the above, the inventors of the present invention made diligent studies and produced a primary sheet with use of not a melt-kneaded product to which no solvent is added but a mixture containing the graphite particles (A), the organic polymer compound (B), and a solvent. As a result, the inventors of the present invention have found that it is possible to obtain, by providing the primary sheet to the laminate formation step and the slicing step, a thermally conductive sheet in accordance with an embodiment of the present invention in which the tensile strength (X) and the tensile strength (Y) are controlled in ranges that satisfy the feature A.

A reason why the tensile strength (X) and the tensile strength (Y) were controlled, by use of the mixture, in the ranges that satisfy the feature A is not clear. However, as the reason, it is inferred that the solvent made a degree of dispersion of the graphite particles (A) and the organic polymer compound (B) inside the primary sheet different from that in a surface of the primary sheet, and this difference was reflected in the laminate. Note that the present invention is not, however, limited to such an inference.

Examples of the solvent include: aromatic hydrocarbon solvents such as toluene and xylene; ester-based solvents such as ethyl acetate and butyl acetate; ketone-based solvents such as methyl ethyl ketone and methyl isobutyl ketone (MIBK); and cellosolve-based solvents such as butyl cellosolve, phenyl cellosolve, and dimethyl cellosolve. The amount of the solvent is preferably such that the total concentration of the graphite particles (A), the organic polymer compound (B), and the additive(s) is 10 parts by weight to 50% by weight, and is more preferably such that the total concentration of the graphite particles (A), the organic polymer compound (B), and the additive(s) is 20 parts by weight to 40% by weight. The primary sheet that is produced at this concentration is preferable because there is a moderate space between the graphite particles, so that orientation of the graphite particles is improved during sheet production and lamination pressing.

The primary sheet forming step is preferably a step of forming the primary sheet by coating. Such a step is also called a solvent casting method, in which the mixture is poured into a mold and dried, so that a primary sheet is obtained. The method is preferable because the tensile strength (X) and the tensile strength (Y) can be more suitably controlled in the ranges that satisfy the feature A. In the above step, the solvent is removed.

The thickness of the composition formed in sheet form is preferably not less than 20 times, and more preferably 20 times to 100 times the average of the maximum length or the major axis of the graphite particles (A). The thickness that is in the above range makes it possible to obtain a high strength sheet and thus is preferable.

### (Laminate Forming Step)

The laminate forming step is a step of laminating the primary sheet to obtain a primary sheet laminate. A method for laminating the primary sheet is exemplified by, but not particularly limited to, a method in which a plurality of primary sheets are stacked and a method in which a primary sheet is folded. The primary sheet is preferably laminated with the graphite particles (A) aligned in the sheet surface.

Pressure at which the primary sheet is laminated is not particularly limited and need only be adjusted to be so weak as not to break a slice surface in a subsequent slicing step and so strong as to achieve successful adhesion between primary sheets. Further, lamination may be carried out under heating as appropriate.

The pressure at which the primary sheet is laminated may be applied every time a single primary sheet is laminated, may be applied for each plurality of primary sheets, or may be applied after all primary sheets are stacked. Preferable examples of a method for applying the pressure include a method in which pressure is applied every time a single primary sheet or each plurality of primary sheets is/are laminated/stacked and pressure is also applied after all primary sheets are stacked. In such a case, pressure and temperature that are applied every time a single primary sheet or each plurality of primary sheets is/are laminated/stacked are not particularly limited. For example, the pressure is 1 kgf/cm² to 100 kgf/cm², and the temperature is 20 °C to 200 °C. Pressure and temperature that are applied after all primary sheets are stacked are also not particularly limited. For example, the pressure is 1 kgf/cm² to 100 kgf/cm², and the temperature is 20 °C to 200 °C.

### (Slicing Step)

In the slicing step, a multilayer cross section of the primary sheet laminate is sliced, so that a thermally conductive sheet is obtained. An angle at which the multilayer cross section of the primary sheet laminate is sliced is not particularly limited. The multilayer cross section of the primary sheet laminate is sliced at an angle of preferably not more than 45°, even more preferably at an angle of 0° to 30°, and particularly preferably at an angle of 0° to 15° relative to the layer-stacking direction, so that a thermally conductive sheet is obtained. By slicing at an angle of not more than 45° relative to the layer-stacking direction, it is possible to obtain a thermally conductive sheet that has excellent thermal conductivity.

A method for slicing the primary sheet laminate is exemplified by, but not particularly limited to, a multi-blade method, a laser processing method, a water jet method, and a knife processing method.

### <Recap>

An embodiment of the present invention includes any of the following features.

<1> A thermally conductive sheet comprising a composition containing graphite particles (A) and an organic polymer compound (B),
the graphite particles (A) being oriented in a thickness direction of the thermally conductive sheet,
the thermally conductive sheet having:
a tensile strength of less than 0.8 MPa in at least one of an X direction and a Y direction; and
a ratio of the tensile strength in the X direction to the tensile strength in the Y direction (the tensile strength in the X direction/the tensile strength in the Y direction) of more than 2.2 times.
   <2> The thermally conductive sheet according to <1>, wherein the graphite particles has a (110) plane orientation degree of not less than 0.010 but less than 0.081, the (110) plane orientation degree being calculated by a lotgering method with use of an X-ray diffraction profile.
   <3> The thermally conductive sheet according to <1> or <2>, wherein the graphite particles has a (110) plane orientation degree of not less than 0.010 but less than 0.045, the (110) plane orientation degree being calculated by a lotgering method with use of an X-ray diffraction profile.
   <4> The thermally conductive sheet according to any one of <1> to <3>, wherein the graphite particles has a (002) plane orientation degree of not less than −0.10 but not more than 0.40, the (002) plane orientation degree being calculated by a lotgering method with use of an X-ray diffraction profile.
   <5> The thermally conductive sheet according to any one of <1> to <4>, wherein the graphite particles has an orientation degree of not less than 0.10 but less than 0.37, the orientation degree being calculated by the following Expression (1) with use of an X-ray diffraction profile,

the orientation degree of the graphite particles=[total vertical count+(total oblique count/2)]/horizontal count (1),

where: the total vertical count is a total of a (100) plane orientation degree and the (110) plane orientation degree; the total oblique count is a total of the (101) plane orientation degree and the (112) plane orientation degree; and the horizontal count is the (002) plane orientation degree.
<6> The thermally conductive sheet according to any one of <1> to <5>, wherein the organic polymer compound (B) includes an acrylic resin including a functional group.
<7> The thermally conductive sheet according to any one of <1> to <6>, wherein the organic polymer compound (B) includes an acryl block copolymer.
<8> The thermally conductive sheet according to any one of <1> to <7>, further comprising a tackifier.
<9> The thermally conductive sheet according to any one of <1> to <8>, further comprising not more than 20% by weight of a plasticizer relative to a total weight of the thermally conductive sheet.
<10> The thermally conductive sheet according to any one of <1> to <9>, further comprising an anti-aging agent.

### EXAMPLES

The following description will discuss an embodiment of the present invention in more detail with reference to Examples and Comparative Examples. Note, however, that the present invention is not limited to these examples.

### [Evaluation Methods]

Evaluation methods in Examples and Comparative Examples will be described below.

### <Thickness>

A 3 mm square piece was cut out from a thermally conductive sheet and used as an evaluation sample. The thickness in four corner parts and one central part of the evaluation sample was measured with use of a micrometer manufactured by Mitutoyo Corporation, and an average of obtained measurement values was regarded as the thickness of the thermally conductive sheet. Note here that “one central part” refers to the position of an intersection of two diagonal lines when diagonal lines are drawn from the four corner parts to diagonally located measurement sites.

### <Tensile Strength (X), Tensile Strength (Y), and Tensile Strength Ratio>

A thermally conductive sheet that was punched out so as to be a piece having a size of 50 mm×20 mm in the X direction and the Y direction. This piece of the thermally conductive sheet was used as a test piece. The test piece thus obtained was subjected to a tensile test in the X direction in which the test piece was pulled in the X direction with use of a compact universal material testing machine (product name: Model 5565, manufactured by Instron Corporation) under the following conditions: an inter-chuck distance of 30 mm and a tensile speed of 20 mm/min. The maximum strength (N) in the tensile test in the X direction was divided by the thickness (mm) of the test piece, and the tensile strength in the X direction, that is, the tensile strength (X) of the thermally conductive sheet was calculated.

The tensile test in the Y direction was carried out by the same method as the tensile test in the X direction except that the direction in which the thermally conductive sheet was pulled was changed to the Y direction. As in calculation of the tensile strength (X), the maximum strength (N) in the tensile test in the Y direction was divided by the thickness (mm) of the test piece, and the tensile strength in the Y direction, that is, the tensile strength (Y) of the thermally conductive sheet was calculated.

The tensile strength (X) and tensile strength (Y) thus calculated were used to calculate a ratio of the tensile strength in the X direction to the tensile strength in the Y direction (the tensile strength in the X direction/the tensile strength in the Y direction), that is, the tensile strength ratio.

Note that in the above-described tensile test, a direction perpendicular to the layer-stacking direction in the laminates prepared in Examples 1 to 4 and Comparative Example 1, which will be described later, was defined as the X direction in the thermally conductive sheet. In addition, a direction perpendicular to the X direction, that is, a direction consistent with the layer-stacking direction in the laminate, was defined as the Y direction.

### < (110) Plane Orientation Degree of Graphite Particles>

A thermally conductive sheet was cut into an approximately 15 mm square piece, and measurement was carried out by a wide angle X-ray diffraction method such that lines of a striped pattern were perpendicular to a direction in which X-ray entered. An XRD profile was obtained by subjecting the surface of the thermally conductive sheet to measurement for X-ray diffraction intensity with use of an X-ray diffraction device (product name: D8 ADVANCE, manufactured by Bruker Corporation) under the following conditions: a scan range of 20° to 90°, a step size of 0.0153°, a voltage of 40 KV, and a current of 40 mA. The (110) plane orientation degree of the graphite particles was calculated, by a lotgering method, from the XRD profile obtained. Specifically, a lotgering factor f₁₁₀ for the (110) plane orientation degree of the graphite particles was calculated according to the following procedure. The lotgering factor f₁₁₀ was calculated by the following Expression (2) with use of a peak intensity of an X-ray that was diffracted from a target crystal plane.

f₁₁₀=(ρ−ρ0)/(1−ρ0) (2)

Note here that ρ0 in Expression (2) was calculated with use of an X-ray diffraction intensity (I0) of a non-oriented sample. Specifically, ρ0 was calculated, by Expression (3) below, as a ratio of the sum of diffraction intensities of (110) planes (Σ10 ((110) plane)) to the sum of all of diffraction intensities (ΣI0 (hkl)) in the non-oriented sample. The graphite particles have a shape that allows the graphite particles to be easily oriented. Thus, even when the graphite particles are in powder form, the graphite particles are easily oriented when a sample is loaded. In light of this, in the present study, the inventors decided to use, for the X-ray diffraction intensity of the non-oriented sample, a peak intensity ratio of ICSD data that had been calculated from a crystal structure.

ρ0=ΣI0((110) plane)/ΣI0(hkl) (3)

The ρ in Expression (2) was calculated with use of an X-ray diffraction intensity (I) of an oriented sample (thermally conductive sheet). Specifically, ρ was calculated, by Expression (4) below, as a ratio of the sum of diffraction intensities of the (110) planes (ΣI ((110) plane)) to the sum of all of diffraction intensities (ΣI (hkl)) in primary sheets.

ρ=ΣI((110) plane)/ΣI(hkl) (4)

Note that in the above, the diffraction intensity means a peak height of a target oriented plane in the XRD profile. In the case of (110) plane orientation, the diffraction intensity means a peak height of 2θ=77° corresponding to the (110) plane.

### < (002) Plane Orientation Degree of Graphite Particles>

The (002) plane orientation degree of the graphite particles was calculated, by the lotgering method, from an XRD profile which was the same as the XRD profile used in calculation of the (110) plane orientation degree of the graphite particles. Specifically, a lotgering factor f₀₀₂ for the (002) plane orientation degree of the graphite particles was calculated according to the following procedure. The lotgering factor f₀₀₂ was calculated by the following Expression (2′) with use of a peak intensity of an X-ray diffracted from a target crystal plane.

f₀₀₂=(ρ′−ρ0′)/(1−ρ0′) (2″)

Note here that ρ0′ in Expression (2′) was calculated with use of an X-ray diffraction intensity (I0) of a non-oriented sample. Specifically, ρ0′ was calculated, by Expression (3′) below, as a ratio of the sum of diffraction intensities of (002) planes (ΣI0 ((002) plane)) to the sum of all of diffraction intensities (ΣI0 (hkl)) in the non-oriented sample. Note that, in the same manner as calculation of the (110) plane orientation degree of the graphite particles, the inventors decided to use, for the X-ray diffraction intensity of the non-oriented sample, a peak intensity ratio of ICSD data that had been calculated from a crystal structure.

ρ0′=ΣI0((002) plane)/ΣI0(hkl) (3′)

The ρ′ in Expression (2′) was calculated with use of an X-ray diffraction intensity (I) of an oriented sample (thermally conductive sheet). Specifically, ρ′ was calculated, by Expression (4′) below, as a ratio of the sum of diffraction intensities of the (002) planes (ΣI ((002) plane)) to the sum of all of diffraction intensities (ΣI (hkl)) in primary sheets.

ρ′=ΣI((002) plane)/ΣI(hkl) (4′)

Note that in the above, the diffraction intensity means a peak height of a target oriented plane in the XRD profile. In the case of (002) plane orientation, the diffraction intensity means a peak height of 2θ=25.5° to 27.5° corresponding to the (002) plane.

### <Orientation Degree a of Graphite Particles>

A thermally conductive sheet was cut into an approximately φ12 mm test piece. While the test piece was rotated, the test piece was measured by a wide angle X-ray diffraction method. An XRD profile was obtained by subjecting a surface of the test piece to measurement for X-ray diffraction intensity with use of an X-ray diffraction device (product name: D8 ADVANCE, manufactured by Bruker Corporation) under the following conditions: a scan range of 20° to 90°, a step size of 0.0153°, a test piece rotation speed of 30 rpm, a voltage of 40 KV, and a current of 40 mA. In the XRD profile obtained, a peak intensity of a peak located in a range of 2θ=41.0° to 43.0° was regarded as a (100) plane orientation degree. Meanwhile, a peak intensity of a peak located in a range of 2θ=76.5° to 78.5° was regarded as the (110) plane orientation degree. Further, in the XRD profile obtained, a peak intensity of a peak located in a range of 20=43.5° to 45.5° was regarded as a (101) plane orientation degree. Meanwhile, a peak intensity of a peak located in a range of 2θ=81.5° to 83.5° was regarded as a (112) plane orientation degree. Furthermore, in the XRD profile obtained, a peak intensity of a peak located in a range of 2θ=25.5° to 27.5° was regarded as the (002) plane orientation degree.

The above-described orientation degrees were used to calculate an orientation degree of the graphite particles which is calculated by the following Expression (1), that is, the orientation degree A of the graphite particles.

The orientation degree of the graphite particles=[total vertical count+(total oblique count/2)]/horizontal count (1),

where: the total vertical count is a total of the (100) plane orientation degree and the (110) plane orientation degree; the total oblique count is a total of the (101) plane orientation degree and the (112) plane orientation degree; and the horizontal count is the (002) plane orientation degree.

### <Hardness>

A laminate consisting of only a thermally conductive sheet (laminate before slicing) was used as an evaluation sample for hardness of the thermally conductive sheet to evaluate the hardness at a center of a cross section (6.5 cm×6.5 cm) of the laminate. Note that the laminate is, in more detail, a laminate which is obtained by operations described in <Preparation of laminate> (described later) and which has not been subjected to operations described in <Preparation of thermally conductive sheet> (described later). Specifically, hardness at the center of the cross section of the evaluation sample was measured in accordance with the Asker C method of the Society of Rubber Industry, Japan Standard (SRIS) with use of a hardness meter (ASKER CL-150LJ, manufactured by KOBUNSHI KEIKI CO., LTD.). The hardness at 20 °C is measured under a condition of 20 °C, and the hardness at 70 °C is measured under a condition of 70 °C.

The hardness at 20 °C of the thermally conductive sheet was evaluated by the following criteria:
A (excellent): not less than 84
B (good): not less than 80 and less than 84
C (poor): less than 80

The hardness at 70 °C of the thermally conductive sheet was evaluated by the following criteria:
A (excellent): more than 63
B (good): not less than 80 and less than 84
C (poor): not more than 60

### <Thermal Resistance Value>

A 1 mm square piece was cut out from a thermally conductive sheet and used as an evaluation sample. For the evaluation sample, a thermal resistance value (cm²K/W) of the thermally conductive sheet was obtained by measurement with use of a thermal resistance measurement device (resin material thermal resistance measurement device manufactured by Hitachi Technologies and Services, Ltd.) at a sample temperature of 50 °C and a pressure of 0.5 MPa.

The thermal resistance value of the thermally conductive sheet was evaluated by the following criteria:
A (excellent): a case where the thermal resistance value of the thermally conductive sheet is not more than 0.080 cm²K/W
B (good): a case where the thermal resistance value of the thermally conductive sheet is more than 0.080 cm²K/W and not more than 0.10 cm²K/W
C (poor): a case where the thermal resistance value of the thermally conductive sheet is more than 0.10 cm²K/W

### <Temporary Attachment Property>

The temporary attachment property of the thermally conductive sheet is evaluated by: peeling a 40 mm×40 mm sized piece of the thermally conductive sheet off from a separator; and bonding this piece of the thermally conductive sheet to a 50 mm×50 mm piece of a silicon wafer. The excellent temporary attachment property means the following:
The thermally conductive sheet is easily peeled off from the separator.
The thermally conductive sheet can be fixed and bonded accurately on the silicon wafer.
Even in a case where the silicon wafer is transported or turned upside down, the thermally conductive sheet does not peel off.
The air entrained between the silicon wafer and the thermally conductive sheet is easily released.

The criteria for evaluation are as follows.
A: (excellent) The thermally conductive sheet is easily peeled off from the separator and easily bonded to a silicon wafer, and air is unlikely to be entrained.
B: (good) The thermally conductive sheet is easily peeled off from the separator and easily bonded to a silicon wafer (a little lightly bonded), and air is unlikely to be entrained.
C: (poor) The thermally conductive sheet is difficult to peel off from the separator and too firmly bonded to a silicon wafer, and air is entrained. Alternatively, the thermally conductive sheet peels off too much from the separator and is not bonded to the silicon wafer.

### <Initial Adhesion>

Silicon (50 mm×50 mm×0.7 mm), a thermally conductive sheet (40 mm×40 mm×0.11 mm), and a spreader (nickel-plated copper: 50 mm×50 mm×2 mm) were stacked in this order on a heat press device and set. Subsequently, the heat press device was used to bond the silicon, the thermally conductive sheet, and the spreader in this order under conditions of 150 °C and 100 kg. This resulted in obtainment of an adhesion measurement laminate. Subsequently, a scanning acoustic tomograph (product name: FineSAT, manufactured by Hitachi Power Solutions Co., Ltd.) was used to measure an area of adhesion between the thermally conductive sheet and adherends (the silicon and the spreader) in the adhesion measurement laminate.

The initial adhesion of the thermally conductive sheet was evaluated by the following criteria:
A (excellent): a case where the area of adhesion is not less than 95% of the area of the entire surface on a side of the thermally conductive sheet which side adheres to the adherend
B (good): a case where the area of adhesion is not less than 90% and less than 95% of the area of the entire surface on the side of the thermally conductive sheet which side adheres to the adherend
C (poor): a case where the area of adhesion is less than 90% of the area of the entire surface on the side of the thermally conductive sheet which side adheres to the adherend
   <Adhesion after Maintaining Thermally Conductive Sheet at High Temperature>

An adhesion measurement laminate was obtained by the same method as described in the above <Initial adhesion> section. Subsequently, the adhesion measurement laminate was placed in a heating furnace and then maintained for 500 hours with ambient temperature inside the heating furnace heated to 150 °C. Thereafter, the adhesion measurement laminate was removed from the heating furnace, and an area of adhesion between the thermally conductive sheet and the adherends (the silicon and the spreader) in the adhesion measurement laminate was measured. Adhesion after maintaining the thermally conductive sheet at high temperature was evaluated on the basis of the area of adhesion by the same criteria as the evaluation criteria for the initial adhesion that are described in the above <Initial adhesion> section.

<Adhesion after Heat Cycles>

Adhesion after heat cycles was evaluated by the same method as described in the above <Adhesion after maintaining thermally conductive sheet at high temperature> section, except for matters described below. Note that the adhesion after heat cycles was evaluated by criteria identical to the evaluation criteria for the initial adhesion described in the above <Initial adhesion> section.
An adhesion measurement laminate was placed in a heat shock tester (product name: ES-56L, manufactured by Hitachi Appliances, Ltd.) instead of the heating furnace. Subsequently, a heat cycle was repeated 500 times. In the heat cycle, ambient temperature inside the heat shock tester was raised to 120 °C, then lowered to −40 °C, and subsequently raised again to 120 °C.

### Example 1

### <Preparation of Composition Solution>

A planetary centrifugal mixer was used to stir and mix raw materials (shown below) over 10 minutes to obtain a composition solution. The composition solution had a solid content concentration of 30.0% by weight. The composition solution to a “mixture corresponds containing the graphite particles (A), the organic polymer compound (B), and a solvent” described in the above [2. Method for producing thermally conductive sheets]. Note that a mixture of an acrylic resin having a functional group and an acryl block copolymer, which are described below, falls under the organic polymer compound (B).
As the graphite particles (A), scale-like graphite powder (average particle size: 73 μm, thickness: 0.80 μm, aspect ratio: 91, and sulfur content: not more than 1.0% by weight): 125.71 g;
As the acrylic resin having a functional group, a 15% by weight toluene/ethyl acetate solution containing an acrylic resin (weight average molecular weight: 900,000, Tg: −60 °C, content of a hydroxyl group as the functional group: 0.116 mmol/g, 6.5 KOH mg/g, liquid at normal temperature): 336.76 g (50.51 g as the acrylic resin having a functional group);
As the acryl block copolymer, a 15% by weight toluene/ethyl acetate solution containing an acryl block copolymer (weight average molecular weight: 56,000, Tg: hard segment 100 °C to 120 °C and soft segment −50 °C to −40 °C, without the functional group, liquid at normal temperature): 112.76 g (16.91 g as the acryl block copolymer without a functional group);
A tackifier (hydrogenated petroleum resin having a softening point of 90 °C): 22.86 g;
A plasticizer (polybutene having a weight average molecular weight of 3700): 11.43 g;
An anti-aging agent (amine-based anti-aging agent: 4,4′-bis(α,α-dimethylbenzyl)diphenylamine): 1.14 g; and
Toluene: used in an amount which causes the solid content concentration of the composition solution to be 30.0% by weight.

### <Preparation of Primary Sheet>

The composition solution obtained was applied to and spread on a polyethylene terephthalate film, with a clearance provided, so that a coating film would have a thickness of 2 mm, the polyethylene terephthalate film having a mold release treated surface. Thereafter, a resulting sheet was dried at 120 °C for not less than 20 minutes, and the dried sheet was peeled off to obtain a primary sheet having a thickness of 2 mm. The above operation was repeated three times to produce three primary sheets.

The content of the graphite particles, the organic polymer compound (B), and the anti-aging agent relative to the total weight of the composition contained in the primary sheet corresponds to the content relative to the total weight of the composition contained in a thermally conductive sheet that is finally obtained, i.e., the thermally conductive sheet that is finally obtained.

### <Preparation of Laminate>

A 2.4 cm×6.4 cm sheet was cut out from each of the three primary sheets thus obtained. Every time 5 sheets were stacked in a container having an internal volume of 2.5 cm in length×6.5 cm in width×7.5 cm in height, the stacked sheets were pressed at normal temperature and a pressure of not less than 400 kg, and stacking and pressing were repeated until the pressed sheets had a thickness of not less than 6.5 cm after final pressing. Next, a stack obtained by stacking the sheets until the thickness reached not less than 6.5 cm was heated at 120 °C for 15 minutes and then pressed at a pressure of not less than 400 kg, so that a laminate of 2.5 cm×6.5 cm×6.5 cm was obtained.

### <Preparation of Thermally Conductive Sheet>

By slicing a multilayer cross section of the obtained laminate at an angle of 45 degrees relative to the layer-stacking direction, a thermally conductive sheet was produced which had a size of 6.5 cm in length×6.5 cm in width×110 μm in thickness.

### Examples 2 to 4

A thermally conductive sheet was prepared as in Example 1 except that amounts of the materials used in Example 1 were changed to mixing ratios shown in Table 1. The thermally conductive sheet obtained in each of Examples 2 and 3 had a film thickness of 110 μm, and the thermally conductive sheet obtained in Example 4 had a film thickness of 75 μm.

### Comparative Example 1

While heating, the following were melt-kneaded: as the graphite particles (A), 120 g of a scale-like expanded graphite powder (average particle size: 250 μm, thickness: 5 μm, aspect ratio: 50, and sulfur content: not less than 1.5% by weight); as the organic polymer compound (B), 54 g of an acrylic ester-based resin (weight average molecular weight: 1,200,000, Tg: −37 °C, containing an OH group as a functional group); and 66 g of an aromatic condensed phosphate ester (CR-741, manufactured by Daihachi Chemical Industry Co., Ltd.).

### <Preparation of Primary Sheet>

Part of 240 g of the composition obtained was taken, rolled into a lump, and sandwiched between PTFE films. Then, a press having a tool surface of 10 cm×20 cm was used to press under conditions of a tool pressure of 10 MPa and a tool temperature of 170 °C. As a result, a primary sheet having a thickness of 3 mm was obtained. The above operation was repeated, so that many primary sheets were prepared.

### <Preparation of Laminate>

From each of the primary sheets thus obtained, 2.4 cm×6.4 cm sheets were cut out. Every time 5 sheets were stacked in a container having an internal volume of 2.5 cm in length×6.5 cm in width×7.5 cm in height, the sheets stacked were pressed at normal temperature and a pressure of not less than 400 kg. Such stacking and pressing were repeated until the sheets pressed had an ultimate thickness of not less than 6.5 cm after pressing. Next, a stack obtained by stacking the sheets until the thickness reached not less than 6.5 cm was heated at 120 °C for 15 minutes and then pressed at a pressure of not less than 400 kg, so that a laminate of 2.5 cm×6.5 cm×6.5 cm was obtained.

### <Preparation of Comparative Thermally Conductive Sheet>

By slicing a multilayer cross section of the obtained laminate at an angle of 45 degrees relative to a layer-stacking direction, a comparative thermally conductive sheet was produced which had a size of 6.5 cm in length×6.5 cm in width×250 μm in thickness and in which the graphite particles were oriented in the thickness direction of the thermally conductive sheet.

### [Evaluation of Thermally Conductive Sheets]

Table 1 shows results of measuring, on the basis of the above-described evaluation methods, physical properties of each of the thermally conductive sheets obtained in Examples 1 to 4 and the thermally conductive sheet obtained in Comparative Example 1. Note that in Table 1, the graphite particles (A) and the plasticizer which were used in Examples 1 to 4 are each shown as “A”. Further, the graphite particles (A) and the plasticizer which were used in Comparative Example 1 are each shown as “B”. Further, in Table 1, the acrylic resins which were used in Examples 1 to 4 as the acrylic resin having a functional group and the acrylic ester-based resin which was used in Comparative Example 1 were collectively referred to as “acrylic resin”. In addition, in Table 1, the type of the acrylic resin used in Examples 1 to 4 is indicated as “A”, and the type of the acrylic resin used in Comparative Example 1 is indicated as “B”. The “mixing ratio” refers to a ratio of the solid weight of a material used with respect to the solid weight of all materials except for the solvent. For example, a mixing ratio of “55.0” of the graphite particles in Example 1 indicates that the ratio of the solid weight of the graphite particles (A) used in Example 1 with respect to the solid weight of all materials except for the solvent used in Example 1 is 55.0% by weight.

TABLE 1

| | Example | Example | Example | Example | Comparative |
|---|---|---|---|---|---|
| | 1 | 2 | 3 | 4 | Example 1 |
| Type of | A | A | A | A | B |
| graphite | | | | | |
| particles (A) | | | | | |
| Mixing ratio | 55.0 | 52.5 | 50.5 | 50.5 | 52.5 |
| of graphite | | | | | |
| particles (A) | | | | | |
| [wt %] | | | | | |
| Type of | A | A | A | A | B |
| acrylic resin | | | | | |
| Mixing ratio | 22.1 | 24.0 | 25.5 | 25.5 | 20.0 |
| of acrylic | | | | | |
| resin | | | | | |
| [wt %] | | | | | |
| Mixing ratio | 7.4 | 8.0 | 8.5 | 8.5 | —^{★} |
| of acryl block | | | | | |
| copolymer | | | | | |
| [wt %] | | | | | |
| Mixing ratio | 10.0 | 10.0 | 10.0 | 10.0 | —^{★} |
| of additive | | | | | |
| (tackifier) | | | | | |
| [wt %] | | | | | |
| Type of | A | A | A | A | B |
| additive | | | | | |
| (plasticizer) | | | | | |
| Mixing ratio | 5.0 | 5.0 | 5.0 | 5.0 | 27.5 |
| of additive | | | | | |
| (plasticizer) | | | | | |
| [wt %] | | | | | |
| Mixing ratio | 0.5 | 0.5 | 0.5 | 0.5 | —^{★} |
| of anti-aging | | | | | |
| agent | | | | | |
| [wt %] | | | | | |
| Method of | Mixing | Mixing | Mixing | Mixing | Melt- |
| mixing | by | by | by | by | kneading |
| materials | stirring | stirring | stirring | stirring | without |
| | with use | with use | with use | with use | use |
| | of | of | of | of | of |
| | solvent | solvent | solvent | solvent | solvent |
| Thickness | 110 | 110 | 110 | 75 | 250 |
| [μm] | | | | | |
| Tensile | 0.632 | 0.675 | 0.695 | 0.670 | 0.206 |
| strength (X) | | | | | |
| [MPa] | | | | | |
| Tensile | 0.122 | 0.164 | 0.205 | 0.199 | 0.120 |
| strength (Y) | | | | | |
| [MPa] | | | | | |
| Tensile | 5.2 | 4.1 | 3.4 | 3.4 | 1.7 |
| strength ratio | | | | | |
| (110) plane | 0.044 | 0.040 | 0.032 | 0.033 | 0.081 |
| orientation | | | | | |
| degree of | | | | | |
| graphite | | | | | |
| particles | | | | | |
| (002) plane | 0.152 | 0.225 | 0.300 | 0.304 | −0.120 |
| orientation | | | | | |
| degree of | | | | | |
| graphite | | | | | |
| particles | | | | | |
| Orientation | 0.265 | 0.233 | 0.200 | 0.204 | 0.378 |
| degree based | | | | | |
| on | | | | | |
| Expression | | | | | |
| (1) | | | | | |
| Evaluation of | A | A | A | A | C |
| hardness at | | | | | |
| 20 °C | | | | | |
| Evaluation of | A | A | A | A | C |
| hardness at | | | | | |
| 70 °C | | | | | |
| Evaluation of | A | A | A | A | B |
| thermal | | | | | |
| resistance | | | | | |
| value | | | | | |
| Evaluation of | B | A | A | A | B |
| temporary | | | | | |
| attachment | | | | | |
| property | | | | | |
| Evaluation of | A | A | A | A | C |
| initial | | | | | |
| adhesion | | | | | |
| Evaluation of | A | A | A | A | C |
| adhesion | | | | | |
| after | | | | | |
| maintaining | | | | | |
| at high | | | | | |
| temperature | | | | | |
| Evaluation of | A | A | A | A | C |
| adhesion | | | | | |
| after heat | | | | | |
| cycles | | | | | |

^{★}In Comparative Example 1, “—” indicates that no relevant substance is used.

Here, a scanning electron microscope (product name: ULTRAplus manufactured by Carl Zeiss AG) was used to observe, at a magnification of 50 times to 4,000 times, the thermally conductive sheets produced in Examples 1 to 4. As a result, the graphite particles were observed to be oriented in the thickness direction of the thermally conductive sheets. As shown in Table 1, the thermally conductive sheets produced in Examples 1 to 4 had a tensile strength (Y) of less than 0.8 MPa, and a tensile strength ratio of more than 2.2 times. In contrast, the comparative thermally conductive sheet produced in Comparative Example 1 had a tensile strength ratio of not more than 2.2 times.

Thus, the thermally conductive sheets produced in Examples 1 to 4 fall under the thermally conductive sheet in accordance with an embodiment of the present invention. In contrast, the comparative thermally conductive sheet produced in Comparative Example 1 does not fall under the thermally conductive sheet in accordance with an embodiment of the present invention.

Further, as shown in Table 1, the thermally conductive sheets produced in Examples 1 to 4 had a lower thermal resistance value and were better in terms of thermal conductivity than the comparative thermally conductive sheet produced in Comparative Example 1. The thermally conductive sheets produced in Examples 1 to 4 were also better than the comparative thermally conductive sheet produced in Comparative Example 1 in terms of: the temporary attachment property; and the adhesion expressed as initial adhesion, adhesion after maintaining the thermally conductive sheet at high temperature, and adhesion after heat cycles.

In light of the above, it has been found out that the thermally conductive sheet in accordance with an embodiment of the present invention has an excellent temporary attachment property and excellent adhesion in addition to excellent thermal conductivity.

### INDUSTRIAL APPLICABILITY

A thermally conductive sheet in accordance with an embodiment of the present invention has an excellent temporary attachment property and excellent adhesion in addition to excellent thermal conductivity. Therefore, the thermally conductive sheet in accordance with an embodiment of the present invention can be suitably used to produce a product that is required to have an excellent temporary attachment property and excellent adhesion in addition to excellent thermal conductivity, such as an electronic component including, for example, a multilayer wiring board and a semiconductor package.

1. A thermally conductive sheet comprising a composition containing graphite particles (A) and an organic polymer compound (B),
the graphite particles (A) being oriented in a thickness direction of the thermally conductive sheet,
the thermally conductive sheet having:
a tensile strength of less than 0.8 MPa in at least one of an X direction and a Y direction; and
a ratio of the tensile strength in the X direction to the tensile strength in the Y direction (the tensile strength in the X direction/the tensile strength in the Y direction) of more than 2.2 times.

2. The thermally conductive sheet according to claim 1, wherein the graphite particles has a (110) plane orientation degree of not less than 0.010 but less than 0.081, the (110) plane orientation degree being calculated by a lotgering method with use of an X-ray diffraction profile.

3. The thermally conductive sheet according to claim 1, wherein the graphite particles has a (110) plane orientation degree of not less than 0.010 but less than 0.045, the (110) plane orientation degree being calculated by a lotgering method with use of an X-ray diffraction profile.

4. The thermally conductive sheet according to claim 1, wherein the graphite particles has a (002) plane orientation degree of not less than −0.10 but not more than 0.40, the (002) plane orientation degree being calculated by a lotgering method with use of an X-ray diffraction profile.

5. The thermally conductive sheet according to claim 1, wherein the graphite particles has an orientation degree of not less than 0.10 but less than 0.37, the orientation degree being calculated by the following Expression (1) with use of an X-ray diffraction profile,
the orientation degree of the graphite particles=[total vertical count+(total oblique count/2)]/horizontal count (1),
where: the total vertical count is a total of a (100) plane orientation degree and the (110) plane orientation degree; the total oblique count is a total of the (101) plane orientation degree and the (112) plane orientation degree; and the horizontal count is the (002) plane orientation degree.

6. The thermally conductive sheet according to claim 1, wherein the organic polymer compound (B) includes an acrylic resin including a functional group.

7. The thermally conductive sheet according to claim 1, wherein the organic polymer compound (B) includes an acryl block copolymer.

8. The thermally conductive sheet according to claim 1, further comprising a tackifier.

9. The thermally conductive sheet according to claim 1, further comprising not more than 20% by weight of a plasticizer relative to a total weight of the thermally conductive sheet.

10. The thermally conductive sheet according to claim 1, further comprising an anti-aging agent.
